(19) United States
(12) Patent Application Publication
(10) Pub. No.: US 2026/0191119 A1
(43) Pub. Date: Jul. 2, 2026

(54) CRYOGENIC DIE TO DIE ELECTRICAL CONNECTORS

(71) Applicant: PsiQuantum, Corp., Palo Alto, CA (US)

(72) Inventors: Vijay SUKUMARAN, San Jose, CA (US); Kishor DESAI, Fremont, CA (US); Benjamin BRIGGS, Albany, NY (US); Himani KAMINENI, Ballston Spa, NY (US)

(21) Appl. No.: 19/131,886

(22) PCT Filed: Nov. 16, 2023
(86) PCT No.: PCT/US2023/080046

§ 371 Date: May 21, 2025

Related U.S. Application Data
(60) Provisional application No. 63/384,716, filed on Nov. 22, 2022.

(51) Int. Cl. H10W 90/00; H10W 90/26; H10W 90/28

(52) U.S. Cl. CPC H10W 90/762; H10W 90/26; H10W 90/28

(57) ABSTRACT

A hybrid electronic/photonic device includes a first photonic die containing first photonic components, a first electronic die electrically connected to the first photonic die, a first electrical interposer bonded to the first electronic die; and an electrical coupler coupled to the first electrical interposer such that at least a first portion of the electrical coupler coupled to the first electrical interposer and the first electrical interposer have respective coefficients of thermal expansion that differ by 10% or less.

### TECHNICAL FIELD

Embodiments herein relate generally to cryogenic photonic and electronic chip assemblies used for quantum computing (QC) applications, and more specifically to cryogenic electrical connectors used to connect electronic die to one another.

### BACKGROUND

A cryostat is a device that is used to maintain cryogenic temperatures (e.g., 120° K. or less) for objects or materials located within the cryostat. Cryostats have been used for a number of applications in which cryogenic temperatures are desirable and/or necessary. For example, many types of quantum computing (QC) systems require quantum processing operations to be performed at extremely low temperatures. A cryostat may be used to house components of the QC system used to perform quantum processing operations such that these components may be maintained within a specified cryogenic temperature range.

### SUMMARY

According to one embodiment, a hybrid electronic/photonic device includes a first photonic die containing first photonic components, a first electronic die electrically connected to the first photonic die, a first electrical interposer bonded to the first electronic die; and an electrical coupler coupled to the first electrical interposer such that at least a first portion of the electrical coupler coupled to the first electrical interposer and the first electrical interposer have respective coefficients of thermal expansion that differ by 10% or less.

According to another embodiment, a hybrid electronic/photonic device comprises a substrate, first and second die stacks located over the substrate, and an electrical coupler electrically coupling the first and the second die stacks. The first die stack comprises a first photonic die comprising first photonic components, a first electronic die electrically connected to the first photonic die, and a first electrical interposer bonded to the first electronic die. The second die stack comprises a second photonic die comprising second photonic components, a second electronic die electrically connected to the second photonic die, and second electrical interposer bonded to the second electronic die. The electrical coupler comprises a rigid first connector comprising a semiconductor or insulating matrix embedding electrically conducting elements which are electrically connected to the first electrical interposer, a rigid second connector comprising a semiconductor or insulating matrix embedding electrically conducting elements which are electrically connected to the second electrical interposer, and a flexible cable located above the substrate and electrically connecting the rigid first and second connectors.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1A is a simplified schematic diagram illustrating an optical switch, according to some embodiments.

FIG. 1B is an illustration of a user interfacing with a hybrid quantum computing device, according to some embodiments.

FIG. 2A is a top view of a hybrid electronic/photonic device that may form a sub-system of a hybrid computing system, according to some embodiments.

FIG. 2B is a vertical cross-sectional view of a first portion of the hybrid electronic/photonic device including die stacks, according to some embodiments.

FIG. 2C is a vertical cross-sectional view of the first portion of the hybrid electronic/photonic device in which the die stacks have an alternative configuration, according to some embodiments.

FIG. 2D is a vertical cross-sectional view of a second portion of the hybrid electronic/photonic device, according to some embodiments.

FIG. 3A is an enlarged vertical cross-sectional view of a portion of the hybrid electronic/photonic device of FIG. 2D including a first connector, according to some embodiments.

FIG. 3B is an enlarged vertical cross-sectional view of the first connector of FIG. 3A, according to some embodiments.

FIG. 3C is a horizontal cross-sectional view of a top surface of an electrical interposer showing a plurality of electrically conductive connectors, according to some embodiments.

FIG. 3D is a vertical cross-sectional view of a portion of the first connector of FIG. 3B, according to some embodiments.

FIG. 4A is a horizontal cross-sectional view of a first portion of a plate having straight grooves, according to some embodiments.

FIG. 4B is a horizontal cross-sectional view of a first portion of a plate having grooves formed in a fan-out configuration, according to some embodiments.

FIG. 4C is a horizontal transparent top view of grooves of two stacked plates in a first configuration, according to some embodiments.

FIG. 4D is a horizontal transparent top view of grooves of two stacked plates in a second configuration, according to some embodiments.

FIG. 5A is a vertical cross-sectional view of a portion of the first connector of FIG. 3B in which the plate includes passive electrical components, according to some embodiments.

FIG. 5B is a horizontal cross-sectional view of a first portion of a plate having passive electrical components, according to some embodiments.

FIG. 6 is a vertical cross-sectional view of a vertical portion and a connector of one of a plurality of electrically conducting elements, according to some embodiments.

FIG. 7A is a side view of a cable having a plurality of electrically conductive elements, according to some embodiments.

FIG. 7B is a vertical cross-sectional view of the cable of FIG. 7A, according to some embodiments.

FIG. 7C is a vertical cross-sectional view of one of the electrically conductive elements of the cable shown in FIG. 7B, according to some embodiments.

FIG. 7D is a vertical cross-sectional view of one of the electrically conductive elements having a different configuration from that of FIG. 7C, according to some embodiments.

FIG. 8A illustrates a differential pair conductor that may be used as one of the electrically conductive elements in the cable of FIG. 7A, according to an embodiment.

FIG. 8B illustrates a coplanar waveguide that may be used as one of the electrically conductive elements in the cable of FIG. 7A, according to an embodiment.

FIG. 8C illustrates a pair of co-axial conductors that may be used as one of the electrically conductive elements in the cable of FIG. 7A, according to an embodiment.

FIG. 8D illustrates a strip line conductor that may be used as one of the electrically conductive elements in the cable of FIG. 7A, according to an embodiment.

FIG. 8E illustrates a micro-strip line conductor that may be used as one of the electrically conductive elements in the cable of FIG. 7A, according to an embodiment.

FIG. 8F illustrates a plurality of shielded conductors that may be used as one of the additional electrically conductive elements in the cable of FIG. 7A, according to an embodiment.

FIG. 9A illustrates a differential pair conductor having a superconducting material that may be used as one of the electrically conductive elements in the cable of FIG. 7A, according to an embodiment.

FIG. 9B illustrates a coplanar waveguide having a superconducting material that may be used as one of the electrically conductive elements in the cable of FIG. 7A, according to an embodiment.

FIG. 9C illustrates a pair of co-axial conductors having a superconducting material that may be used as one of the electrically conductive elements in the cable of FIG. 7A, according to an embodiment.

FIG. 9D illustrates a strip line conductor having a superconducting material that may be used as one of the electrically conductive elements in the cable of FIG. 7A, according to an embodiment.

FIG. 9E illustrates a micro-strip line conductor having a superconducting material that may be used as one of the electrically conductive elements in the cable of FIG. 7A, according to an embodiment.

FIG. 9F illustrates a plurality of shielded conductors having a superconducting material that may be used as one of the electrically conductive elements in the cable of FIG. 7A, according to an embodiment.

FIG. 10A illustrates a differential pair conductor having a superconducting material and an optical shield that may be used as one of the electrically conductive elements in the cable of FIG. 7A, according to an embodiment.

FIG. 10B illustrates a coplanar waveguide having a superconducting material and an optical shield that may be used as one of the electrically conductive elements in the cable of FIG. 7A, according to an embodiment.

FIG. 10C illustrates a pair of co-axial conductors having a superconducting material and an optical shield that may be used as one of the electrically conductive elements in the cable of FIG. 7A, according to an embodiment.

FIG. 10D illustrates a strip line conductor having a superconducting material and an optical shield that may be used as one of the electrically conductive elements in the cable of FIG. 7A, according to an embodiment.

FIG. 10E illustrates a micro-strip line conductor having a superconducting material and an optical shield that may be used as one of the electrically conductive elements in the cable of FIG. 7A, according to an embodiment.

FIG. 10F illustrates a plurality of shielded conductors having a superconducting material and an optical shield that may be used as one of the electrically conductive elements in the cable of FIG. 7A, according to an embodiment.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

Reference will now be made in detail to embodiments, examples of which are illustrated in the accompanying drawings. In the following detailed description, numerous specific details are set forth to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

It will also be understood that, although the terms first, second, etc. are, in some instances, used herein to describe various elements, these elements should not be limited by these terms. These terms are used only to distinguish one element from another. For example, a first electrode layer could be termed a second electrode layer, and, similarly, a second electrode layer could be termed a first electrode layer, without departing from the scope of the various described embodiments. The first electrode layer and the second electrode layer are both electrode layers, but they are not the same electrode layer.

The following description, for purpose of explanation, is described with reference to specific embodiments. However, the illustrative discussions that follow are not intended to be exhaustive or to limit the scope of the claims to the precise forms disclosed. Many modifications and variations are possible in view of the above teachings. The embodiments were chosen to best explain the principles underlying the claims and their practical applications, to thereby enable others skilled in the art to best use the embodiments with various modifications as are suited to the particular uses contemplated.

Embodiments of the present disclosure provide electrical couplers that may be used at cryogenic temperatures. In one embodiment, the electrical couplers include materials having thermal expansion coefficients that are matched to other components, such as electrical interposers, to which they are mechanically coupled. As such, the embodiment electrical couplers may avoid degradation and damage due to thermal expansion mismatch that may otherwise occur if electrical couplers designed for room temperature use are mechanically coupled to the electrical interposers.

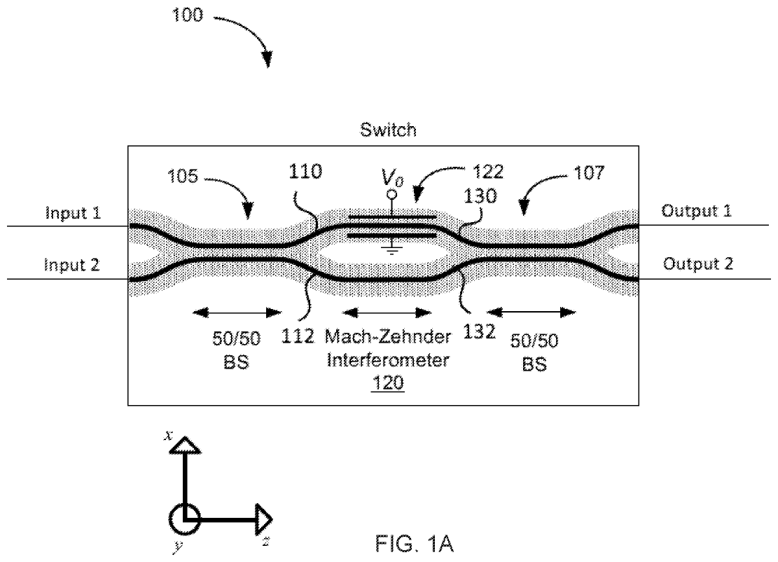

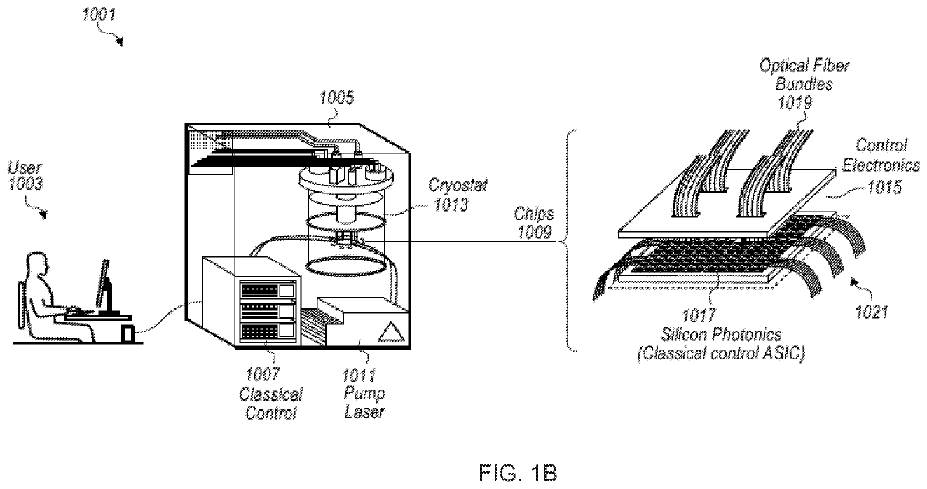

FIG. 1A is a simplified schematic diagram illustrating an optical switch according to an embodiment of this disclosure. Referring to FIG. 1A, electro-optic switch 100 includes two inputs: Input 1 and Input 2 as well as two outputs: Output 1 and Output 2. As an example, the inputs and outputs of the electro-optic switch 100 can be implemented as optical waveguides operable to support single mode or multimode optical beams. As an example, the electro-optic switch 100 can be implemented as a Mach-Zehnder interferometer integrated with a set of 50/50 beam splitters 105 and 107, respectively. As illustrated in FIG. 1A, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112. Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage V₀ can be applied across the waveguide in phase adjustment section 122 such that it can have an index of refraction in phase adjustment section 122 that is controllably varied. Because light in waveguides 110 and 112 still have a well-defined phase relationship (e.g., they may be in-phase, 180° out-of-phase, etc.) after propagation through the first 50/50 beam splitter 105, phase adjustment in phase adjustment section 122 can introduce a predetermined phase difference between the light propagating in waveguides 130 and 132. As will be evident to one of skill in the art, the phase relationship between the light propagating in waveguides 130 and 132 can result in output light being present at Output 1 (e.g., light beams are in-phase) or Output 2 (e.g., light beams are out of phase), thereby providing switch functionality as light is directed to Output 1 or Output 2 as a function of the voltage V₀ applied at the phase adjustments section 122. Although a single active arm is illustrated in FIG. 1A, it will be appreciated that both arms of the Mach-Zehnder interferometer can include phase adjustment sections.

As illustrated in FIG. 1A, electro-optic switch technologies, in comparison to all-optical switch technologies, utilize the application of the electrical bias (e.g., V₀ in FIG. 1A) across the active region of the switch to produce optical variation. The electric field and/or current that results from application of this voltage bias results in changes in one or more optical properties of the active region, such as the index of refraction or absorbance.

Although a Mach-Zehnder interferometer implementation is illustrated in FIG. 1A, embodiments of this disclosure are not limited to this particular switch architecture and other phase adjustment devices are included within the scope of this disclosure, including ring resonator designs, Mach-Zehnder modulators, generalized Mach-Zehnder modulators, and the like. One of ordinary skill in the art would recognize many variations, modifications, and alternatives.

In some embodiments, the optical phase shifter devices described with respect to FIG. 1A above may be utilized within a quantum computing system, such as the hybrid quantum computing system shown in FIG. 1B. Alternatively, these optical phase shifter devices may be used in other types of optical systems. For example, other computational, communication, and/or technological systems may utilize photonic phase shifters to direct optical signals (e.g., single photons or continuous wave (CW) optical signals) within a system or network, and phase shifter architectures described herein may be used within these systems, in various embodiments.

FIG. 1B is a simplified system diagram illustrating incorporation of an electro-optic switch with a prior art cryostat into a hybrid quantum computing system, according to some embodiments. In order to operate at low temperatures, for example liquid helium temperatures, embodiments of this disclosure integrate the electro-optic switches discussed herein (e.g., see FIG. 1A) into a system that includes cooling systems. Thus, embodiments of this disclosure provide an optical phase shifter that may be used within a hybrid computing system of the type illustrated in FIG. 1B. The hybrid computing system 1001 includes a user interface device 1003 that is communicatively coupled to a hybrid quantum computing (QC) sub-system 1005. The user interface device 1003 may be any type of user interface device, for example, a terminal including a display, keyboard, mouse, touchscreen, and the like. In addition, the user interface device may itself be a computer such as a personal computer (PC), laptop, tablet computer, etc.

In some embodiments, the user interface device 1003 provides an interface with which a user can interact with the hybrid QC subsystem 1005. For example, the user interface device 1003 may run software, such as a text editor, an interactive development environment (IDE), command prompt, graphical user interface, and the like so that the user can program, or otherwise interact with, the QC subsystem to run one or more quantum algorithms. In other embodiments, the QC subsystem 1005 may be pre-programmed and the user interface device 1003 may simply be an interface where a user can initiate a quantum computation, monitor the progress, and receive results from the hybrid QC subsystem 1005. Hybrid QC subsystem 1005 may further include a classical computing system 1007 coupled to one or more quantum computing chips 1009. In some examples, the classical computing system 1007 and the quantum computing chip 1009 can be coupled to other electronic components, e.g., pulsed pump lasers 1011, microwave oscillators, power supplies, networking hardware, etc.

The quantum computing chips 1009 may be housed within a cryostat, for example, cryogenic device 1013. In some embodiments, each of the quantum computing chips 1009 can include one or more constituent chips, e.g., hybrid electronic chip 1015 and integrated photonics chip 1017. The photonics chip 1017 may include the electro-optic switch 100 (e.g., an interferometer) shown in FIG. 1A. Signals can be routed on-and off-chip any number of ways, e.g., via optical interconnects (e.g., optical fiber bundles) 1019 and via other electronic interconnects 1021.

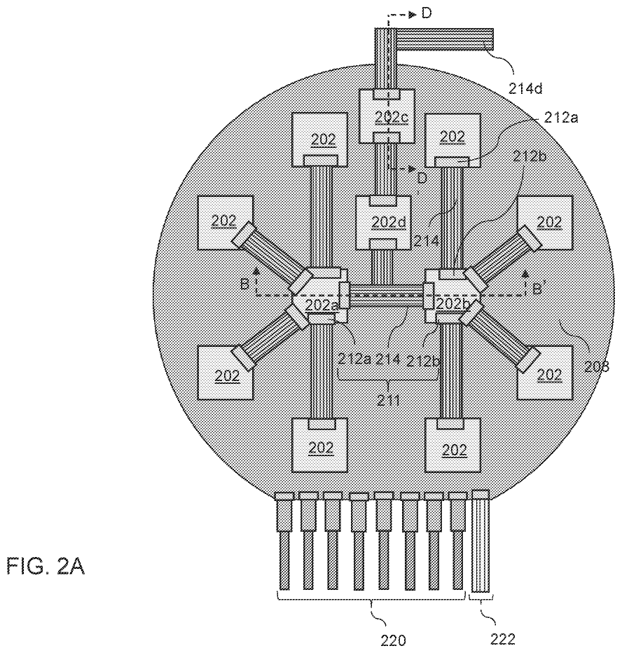

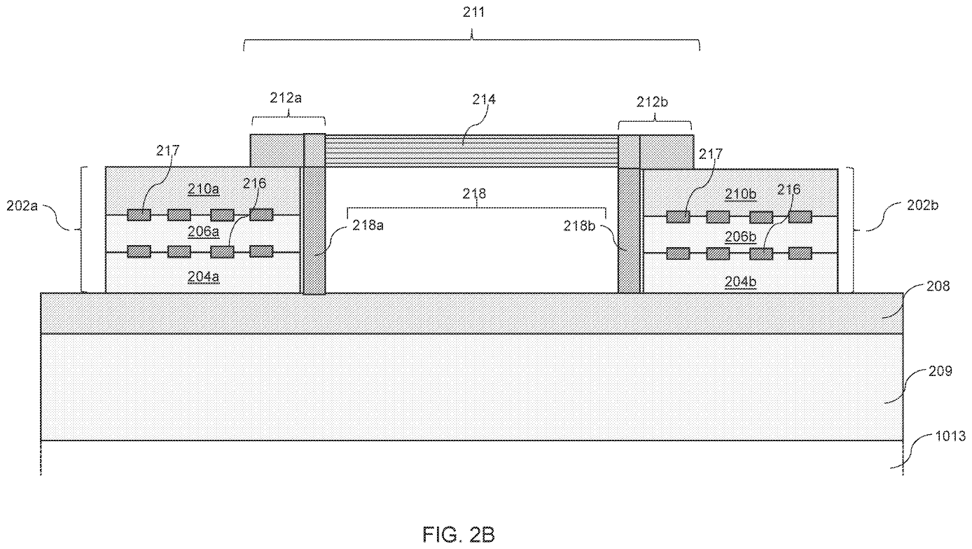

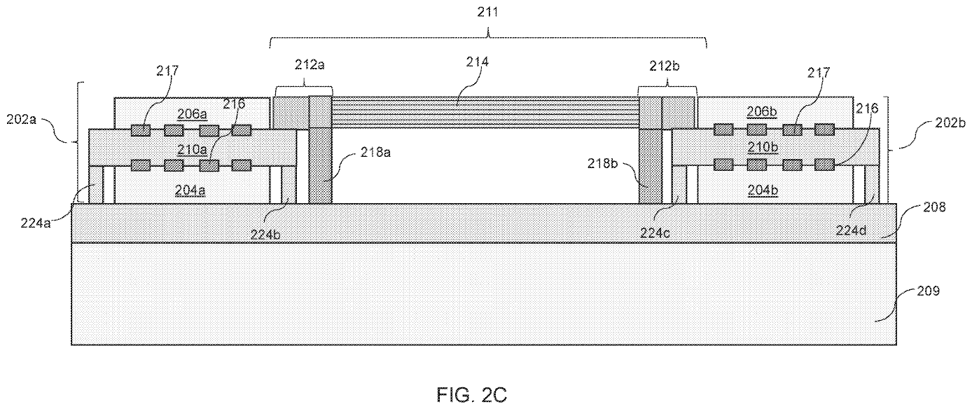

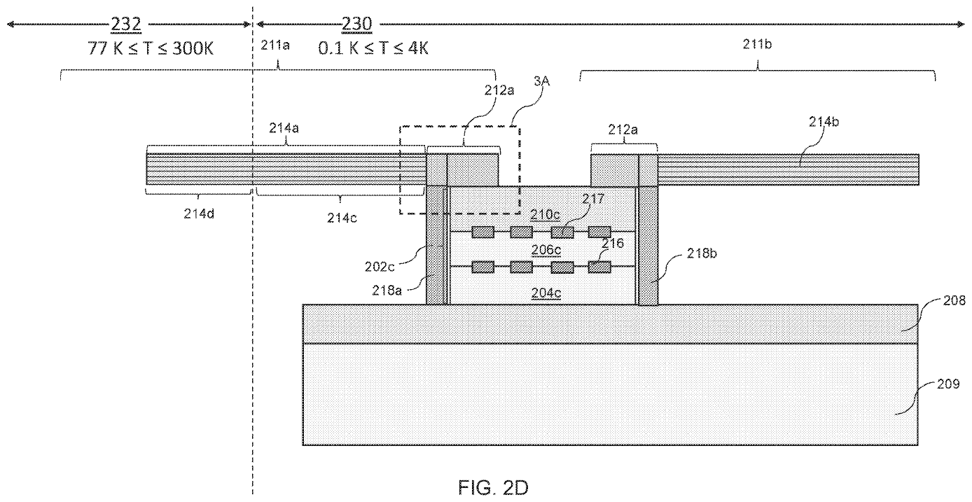

FIG. 2A is a top view of a hybrid electronic/photonic device 200 that may form a component of a hybrid computing system 1001, and FIG. 2B is a vertical cross-sectional view of a first portion of the hybrid electronic/photonic device 200, according to some embodiments. The plane defining the cross-sectional view of FIG. 2B is indicated by the cross-section B-B′ in FIG. 2A. The hybrid electronic/photonic device 200 may include a plurality of die stacks 202, as shown in FIG. 2A. In some embodiments, each of the plurality of die stacks 202 may be structurally similar to one another and may be configured to perform similar electronic and photonic operations. In other embodiments, various different types of die stacks (not shown) may be provided that may be configured to perform respective different electronic and photonic operations.

As shown in FIG. 2B, the first portion of the hybrid electronic/photonic device 200 may include a first die stack 202a and a second die stack 202b. The first die stack 202a and the second die stack 202b may respectively include a first photonic die 204a and a second photonic die 204b. Each of the first photonic die 204a and the second photonic die 204b may be respectively electrically connected to a first electronic die 206a and a second electronic die 206b. In the embodiment shown in FIG. 2B, each of the first photonic die 204a and the second photonic die 204b are directly bonded to the first electronic die 206a and the second electronic die 206b, respectively. Thus, each of the first photonic die 204a and the second photonic die 204b are in direct mechanical contact and in electrical communication to the first electronic die 206a and the second electronic die 206b, respectively.

Each of the first photonic die 204a and the second photonic die 204b may also be optically coupled to one another through a photonic interposer 208. The photonic interposer 208 may be configured to allow optical signals to propagate between the first photonic die 204a and the second photonic die 204b. For example, the photonic interposer 208 may include various photonic transmission pathways, such as optical waveguides. In one embodiment, the photonic interposer comprises a semiconductor substrate, such as a silicon wafer, containing optical waveguides, such as silicon or silicon nitride waveguides. Other materials may also be used for the photonic interposer. The photonic interposer 208 may be directly or indirectly mechanically coupled to a cryogenic device 1013 that may maintain the photonic interposer at cryogenic temperatures (e.g., temperatures between 0.1 K and 4K).

In one embodiment, the photonic interposer 208 may be indirectly mechanically coupled to a cryogenic device 1013 (e.g., a cryostat) through an optional heat spreader 209. Heat generated by the first die stack 202a and the second die stack 202b may be removed by the heat spreader 209. The heat spreader 209 may include a material having a high thermal conductivity that may increase a rate of heat flow from the first die stack 202a and the second die stack 202b through the photonic interposer 208 to the cryogenic device (e.g., such as a liquid helium chamber of the cryogenic device 1013). For example, the heat spreader 209 may comprise a copper plate or silicon wafer that is mounted between the photonic interposer 208 and the cryogenic device 1013. The heat spreader 209 may be maintained at a temperature of 4K or below during operation of the system 1001. Alternatively, the heat spreader 209 may be omitted and the photonic interposer 208 may be directly mechanically coupled to a cryogenic device 1013.

Photonic components (not shown) within each of the first photonic die 204a and the second photonic die 204b may include various electro-optic devices, such as the electro-optic switch 100 described above with reference to FIG. 1A. In this regard, each of the first electronic die 206a and the second electronic die 206b may be electrically coupled to the respective first photonic die 204a and the second photonic die 204b and may provide electrical signals that may be used control photonic operations performed by the first photonic die 204a and the second photonic die 204.

Each of the components of the first die stack 202a and the second die stack 202b may be fabricated using solid state (e.g., semiconductor) device fabrication processes and materials. Similarly, bonding practices used in the semiconductor device industry may be used to bond the various components of the first die stack 202a and the second die stack 202b. For example, the first photonic die 204a may be bonded to the first electronic die 206a using bonding structures 216, such as bonding pads, bump bonds or solder balls. The second photonic die 204b may be bonded to the second electronic die 206b using the bonding structures 216.

Each of the first die stack 202a and the second die stack 202b may further include a first electrical interposer 210a and a second electrical interposer 210b electrically coupled to the first electronic die 206a and the second electronic die 206b, respectively. In the embodiment shown in FIG. 2B, the first electrical interposer 210a and the second electrical interposer 210b are also mechanically coupled to and are located on the first electronic die 206a and the second electronic die 206b, respectively. For example, the first electrical interposer 210a and the second electrical interposer 210b may be bonded to the first electronic die 206a and the second electronic die 206b, respectively, by one or more bonding structures 217, such as bonding pads, bump bonds or solder balls. In one embodiment, the first electrical interposer 210a and the second electrical interposer 210b may be in physical contact with the first electronic die 206a and the second electronic die 206b, respectively. In another embodiment, the first electrical interposer 210a and the second electrical interposer 210b may be vertically spaced from the first electronic die 206a and the second electronic die 206b, respectively, by the bonding structures 217.

The hybrid electronic/photonic device 200 shown in FIG. 2B may further include electrical coupler 211 coupled to and electrically connecting the first electrical interposer 210a and the second electrical interposer 210b. Electrical signals flow between the first electronic die 206a and the second electronic die 206b through the respective the first electrical interposer 210a and the second electrical interposer 210b and the electrical coupler 211.

The electrical coupler 211 includes a first connector 212a and a second connector 212b that are electrically coupled to one another by a cable 214, such as a flexible cable.

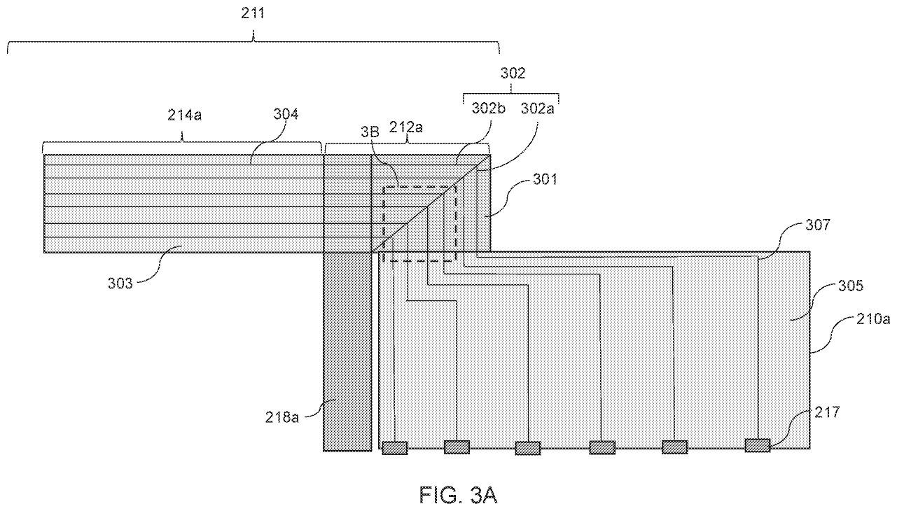

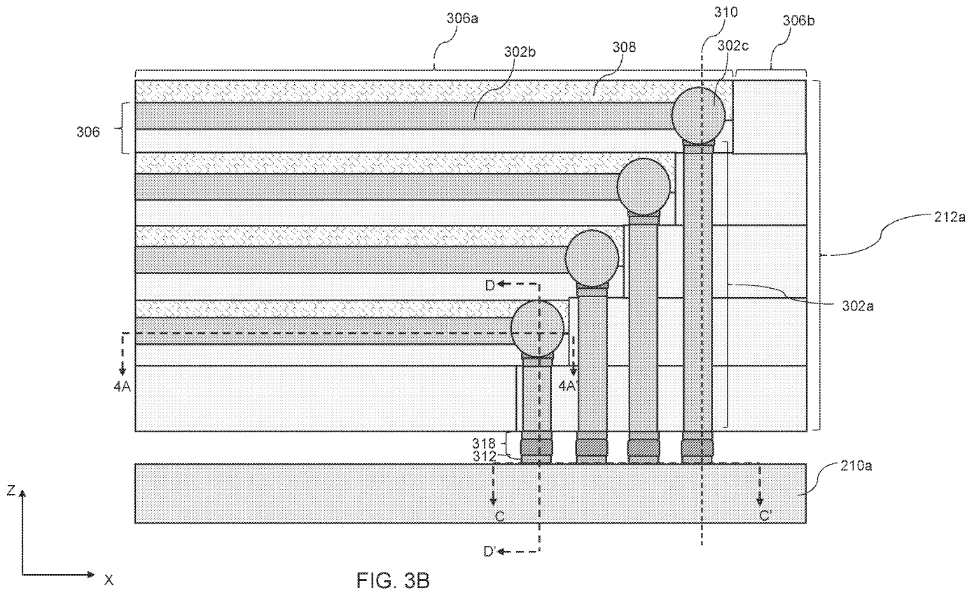

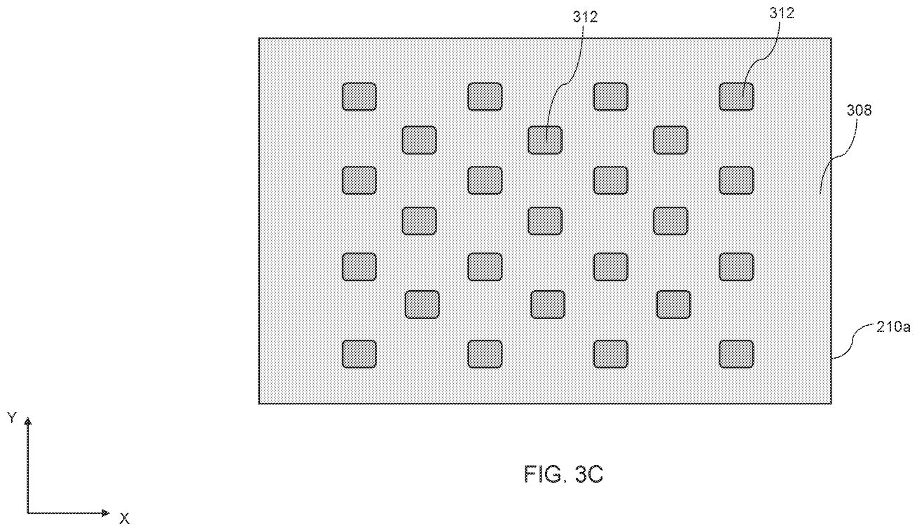

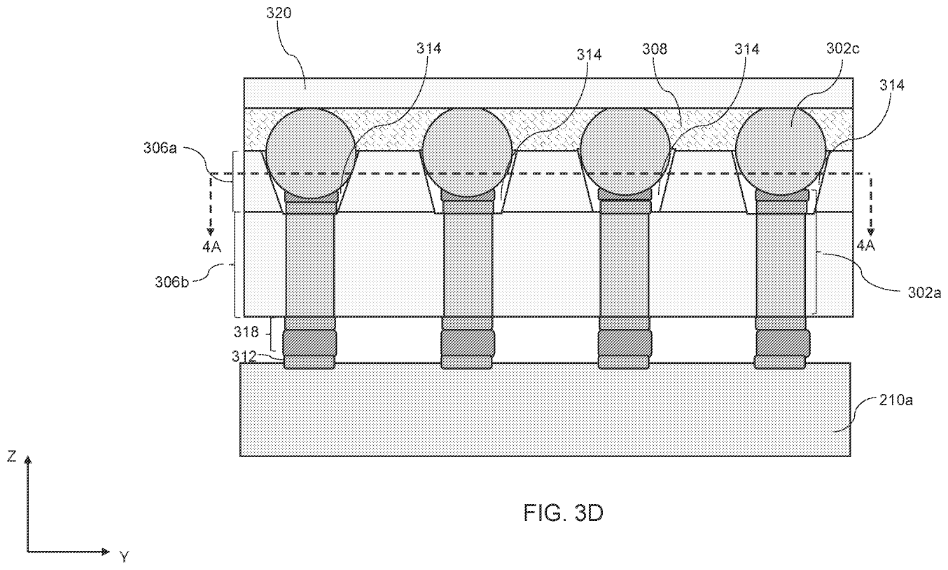

Each of the first connector 212a and a second connector 212b may include electrically conducting elements that may be electrically coupled to the first electrical interposer 210a and the second electrical interposer 210b, respectively, as described in greater detail with reference to FIGS. 3A to 3D, below. The first connector 212a and the second connector 212b may be configured to have a thermal expansion coefficient that differs by 10% or less, such as by 0 to 8%, for example by 1 to 5%, from a thermal expansion coefficient of the first electrical interposer 210a and the second electrical interposer 210b, respectively. In this regard, the first connector 212a, the second connector 212b, the first electrical interposer 210a, and the second electrical interposer 210b may include similar materials, for example, silicon, glass, a ceramic, a polymer material, etc. which contain electrically conductive wires or traces, as will be described in more detail below with reference to FIGS. 3A to 3D.

The electrical coupler 211 may further include a rigid support structure 218 configured to support the first connector 212a and the second connector 212b at a pre-determined distance above a top surface of the photonic interposer 208. For example, the support structure may include a first support portion 218a and a second support portion 218b. As shown in FIG. 2B, for example, the first support portion 218a may be mechanically connected to the first connector 212a and the second support portion 218b may be mechanically connected to the second connector 212b. The first support portion 218a and the second support portion 218b may have any suitable shape, such as a vertical pillar or vertical wall shape. The bottoms of the first support portion 218a and the second support portion 218b may be configured to rest on a top surface of the photonic interposer 208.

As shown in FIG. 2A, the various die stacks 202 in the hybrid electronic/photonic device 200 may be electrically coupled to one another using similar electrical couplers 211. The various components of the hybrid electronic/photonic device 200 may be maintained at cryogenic temperatures such that quantum computing operations may be performed by the hybrid electronic/photonic device 200. Electrical and optical connections may also be formed between the hybrid electronic/photonic device 200, which may be kept at cryogenic temperatures (e.g., 0.1K to 4K), and other system components that may be held at higher temperatures (e.g., 77K to 300 K). For example, a portion 214d of a cable (e.g., shown at the top of FIG. 2A) may electrically connect the hybrid electronic/photonic device 200 to other system components, as described with reference to FIG. 2D, below.

As further shown in FIG. 2A, the hybrid electronic/photonic device 200 may further include plurality of photonic couplers 220 that may be optically coupled to the pump laser 1011 (e.g., see FIG. 1B) to thereby provide laser pump radiation to the hybrid electronic/photonic device 200. One or more additional optical couplers 222 may optically couple photonic signals between the hybrid electronic/photonic device 200 and other components of the hybrid computing system 1001. The photonic signals carried by the one or more additional optical couplers 222 may encode data to be processed by the hybrid electronic/photonic device 200. In this regard, the hybrid electronic/photonic device 200 may be configured to perform one or more quantum computing operations on photonic data provided by the one or more additional optical couplers 222. The one or more additional optical couplers 222 may also provide the results of quantum computing operations performed by the hybrid electronic/photonic device 200 to other sub-systems for further processing or readout.

FIG. 2C is a vertical cross-sectional view of the first portion of the hybrid electronic/photonic device in which the first die stack 202a and the second die stack 202b each have an alternative configuration, according an alternative embodiment. The plane defining the cross-sectional view of FIG. 2C is indicated by the cross-section B-B′ in FIG. 2A. In this alternative embodiment, each of the first die stack 202a and the second die stack 202a include a respective first photonic die 204a and a second photonic die 204b. Each of the first die stack 202a and the second die stack 202a may also include a respective first electronic die 206a and a second electronic die 206b. In contrast to the embodiment of FIG. 2B, however, the first photonic die 204a is not directly connected to the first electronic die 206a and the second photonic die 204b is not directly connected to the second electronic die 206b. Rather, a first electrical interposer 210a may be disposed between the first photonic die 204a and the first electronic die 206a and a second electrical interposer 210b may be disposed between the second photonic die 204b and the second electronic die 206b, as shown in FIG. 2C.

In this alternative embodiment, the first electronic die 206a may be laterally offset from an edge of the top surface of the first electrical interposer 210a. The bottom of the first electrical connector 212a is electrically coupled to the portion of the top surface of the first electrical interposer 210a that is exposed on the side of the laterally offset first electronic die 206a. Furthermore, the second electronic die 206b may be laterally offset from an edge of the top surface of the second electrical interposer 210b. The bottom of the second electrical connector 212b is electrically coupled to the portion of the top surface of the second electrical interposer 210b that exposed on the side of the laterally offset second electronic die 206b.

The alternative embodiment of FIG. 2C may further include a photonic interposer 208 that may be optically coupled to the first photonic die 204a and the second photonic die 204b, as described above with regard to the embodiment of FIG. 2B. Similarly, the first electrical interposer 210a and the second electrical interposer 210b may be electrically coupled to one another with an electrical coupler 211 that includes a first connector 212a, a second connector 212b, and a cable 214 that electrically couples the first connector 212a to the second connector 212b. As shown in FIG. 2C, the first connector 212a may be electrically coupled to the first electrical interposer 210a and the second connector 212b may be electrically coupled to the second electrical interposer 210b. The electrical coupler 211 may further include a support structure having a first support portion 218a and a second support portion 218b mechanically coupled to the first connector 212a and the second connector 212b, respectively. The first support portion 218a and the second support portion 218b may each be configured to support the electrical coupler 211 at a predetermined distance above the photonic interposer 208.

In the alternative embodiment of FIG. 2C, additional support portions (224a, 224b, 224c, 224c) may also be provided. The additional support portions may provide further mechanical support to first electrical interposer 210a and the second electrical interposer 210b, as shown in FIG. 2C. Specifically, the additional support portions may comprise the same material as the first and second electrical interposers, but may lack electrical wires or traces therein. The first and second photonic die 204a, 204b may be laterally offset from edges of the bottom surface of the respective first and second electrical interposers 210a. The top surfaces of the additional support portions (224a, 224b, 224c, 224c) may contact the portions of the bottom surfaces of the respective first and second electrical interposers 210a, 210b that are exposed on the sides of the laterally offset first and second photonic die 204a, 204b. The bottom surfaces of the additional support portions (224a, 224b, 224c, 224c) may rest on the top surface of the photonic interposer 208.

FIG. 2D is a vertical cross-sectional view of a second portion of the hybrid electronic/photonic device 200, according to some embodiments. The plane defining the cross-sectional view of FIG. 2D is indicated by the cross-section D-D′ in FIG. 2A. The second portion of the hybrid electronic/photonic device 200, shown in FIG. 2D, may include a third die stack 202c including a third photonic die 204c, a third electronic die 206c, and a third electrical interposer 210c electrically connected to the third electronic die 206c. The third electrical interposer 210c may be located above the third electronic die 206c, as shown in FIG. 2D, or between the third electronic die 206c and the third photonic die 204c, as shown in FIG. 2C.

The third die stack 202c may be electrically connected to a first electrical coupler 211a having a first cable 214a. The third die stack 202c may be further electrically connected to a second electrical coupler 211b having a second cable 214b. The first cable 214a may be electrically connected to a first connector 212a and the second cable 214b may be electrically connected to a second connector 212b. Further, as in the other embodiments described above, the first connector 212a and the second connector 212b may have a coefficient of thermal expansion that differs by 10% or less from the third electrical interposer 210c of the third die stack 202c. The second cable 214b may connect the third die stack 202c to other components within the hybrid electronic/photonic device 200. For example, the second cable 214b may connect the third die stack 202c to a fourth die stack 202d, as shown in FIG. 2A.

The third die stack 202c may be located near a peripheral region of the hybrid electronic/photonic device 200, as shown in FIG. 2A. As such, the first cable 214a may be configured to extend from a first region 230 to a second region 232. The first region 232 may be a cryogenic region that may be held at cryogenic temperatures, while the second region 232 may be a region that is held at higher temperatures. For example, the first region 230 may be held at liquid helium temperatures (e.g., 0.1K≤T≤4K) while the second region 232 may be held at liquid nitrogen temperatures and above (e.g., 77K≤T≤300K). As such, the first cable 214a may have a first portion 214c extending within region the first region 230 and a second portion 214d extending within the second region 232. Further details of an area 3A of the first electrical connector 212a are described with reference to FIGS. 3A to 3E, below.

FIG. 3A is an enlarged view of area 3A of the hybrid electronic/photonic device 200 of FIG. 2D, according to some embodiments. The view of FIG. 3A includes the first connector 212a, a portion of the first electrical interposer 210a, a portion of the first support portion 218a, and a portion of the first cable 214a. The first connector 212a may include a plurality of electrically conducting elements 302. Each conducting element 302 may comprise a conductive wire or trace which includes a vertical portion 302a and a horizontal portion 302b. The horizontal portion 302b of the electrically conducting elements 302 may extend from the first connector 212a into the first cable 214a. The first cable 214a may include a plurality of additional electrically conductive elements (e.g., wires or traces) 304.

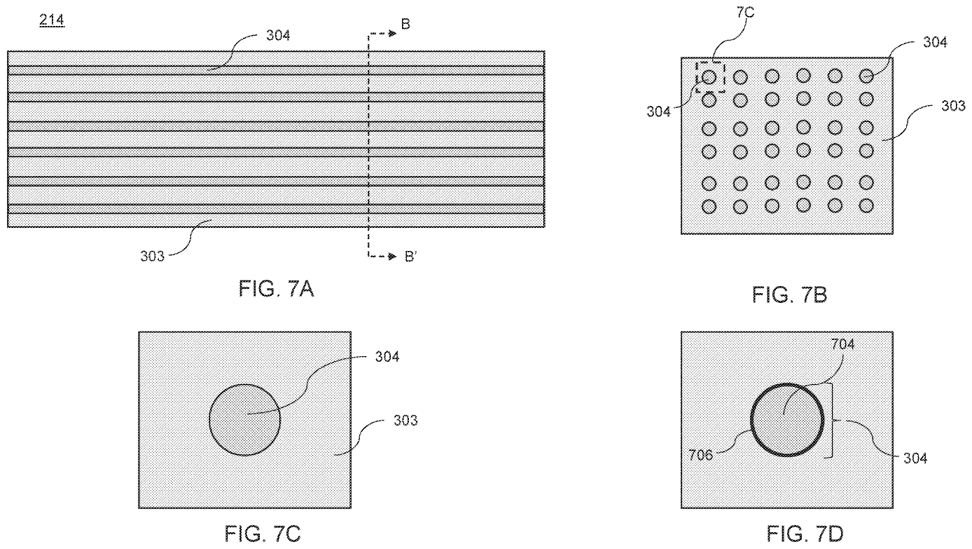

Each of the plurality of additional electrically conductive elements 304 may be electrically connected to a respective horizontal portion 302b of the plurality of electrically conducting elements 302 within the first connector 212a. The plurality of additional electrically conductive elements 304 of the first cable 214a may include various materials and may be configured in various ways, as described in further detail with reference to FIGS. 7A to 10F, below.

In some embodiments, the first cable 214a may include a different material from that of the first connector 212a. In other embodiments, the first cable 214a and the first connector 212a may include similar materials or the same materials. For example, the first connector 212a may include the electrically conducting elements 302 embedded within a semiconductor or insulating matrix 301. The matrix 301 may include one or more of a semiconductor material (e.g., undoped silicon), a glass, a ceramic, or a polymer material. The first cable 214a may include a flexible polymer material (e.g., polyimide) matrix 303 embedding the additional electrically conductive elements 304. For example, the first connector 212a may include a silicon or glass matrix 301 that is mechanically rigid, while the first cable 214a may include a flexible polymer material matrix 303 that allows the first cable 214a to be mechanically flexible.

The electrical interposer 210a may include a plurality of electrically conducting elements 307, such as wires or traces, embedded in a semiconductor or insulating matrix 305. The electrically conducting elements 307 electrically connect the vertical portions 302a of the electrically conducting elements 302 to the bonding structures 217 of the respective electronic die 206c shown in FIG. 2D. Specifically, the electrical interposer 210a spreads out the electrical signals between the dense electrically conducting elements 302 and the spaced apart the bonding structures 217.

The first connector 212a may have a thermal expansion coefficient that differs by 10% or less, such as by 0 to 8%, for example by 1 to 5%, from a thermal expansion coefficient of the first electrical interposer 210a. In this regard, the matrix 301 of first connector 212a and the matrix 306 of first electrical interposer 210a may include the same material, for example, a semiconductor (e.g., silicon), a glass, a ceramic, a polymer material, etc., which contain the respective electrically conductive elements 302 and 307 (e.g., wires, traces). For example, both the first connector 212a and the first electrical interposer 210a may comprise the same matrix, such as for example silicon, which have the same coefficient of thermal expansion. Likewise, the second connector 212b and the second electrical interposer 210b may comprise the same matrix, such as for example silicon, which have the same coefficient of thermal expansion. Furthermore, in one embodiment, the first support portion 218a may comprise the same material as the matrix of the first connector 212a and the first electrical interposer 210a. Likewise, the second support portion 218b may comprise the same material as the matrix of the second connector 212b and the second electrical interposer 210b.

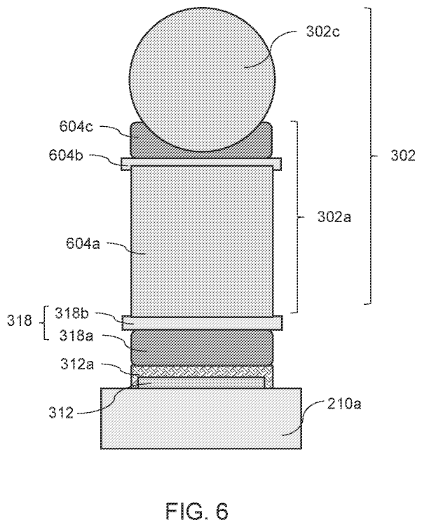

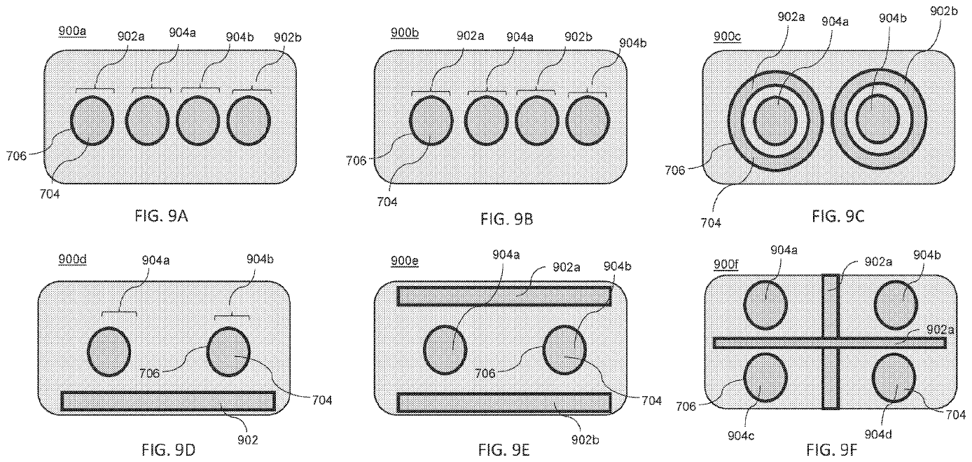

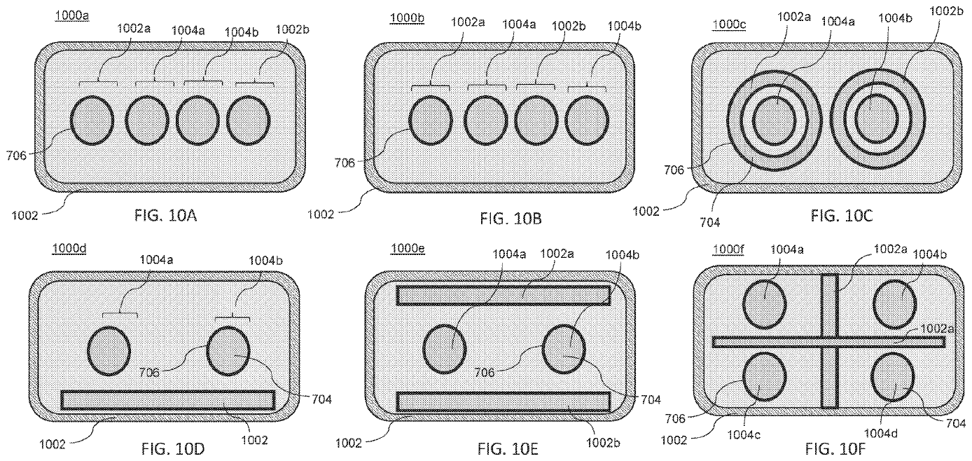

A portion 3B of the of the first connector 212a is described in greater detail with reference to FIG. 3B, below. FIG. 3B is an enlarged vertical cross-sectional view of the first connector 212a and a portion of the first electrical interposer 210a of FIG. 3A, according to some embodiments. As shown in FIG. 3B, each of the plurality of electrically conducting elements 302 of the first connector 212a may include the vertical portion 302a and the horizontal portion 302b. As described in greater detail with reference to FIG. 6, below, the vertical portion 302a may include a multi-layer stack of materials including two or more of copper, indium, gold, and electroless nickel immersion gold. The horizontal portion 302b may include various electrically conducting materials, such as aluminum, copper, etc. In other embodiments, the horizontal portion 302b may include a superconducting material. For example, the horizontal portion 302b may include a copper wire having a coating of a low temperature superconducting material, such as niobium as described in more detail with regard to FIGS. 9A to 10F below. In certain embodiments, the vertical portion 302a may also include a superconducting material. Further, as shown in FIG. 3B, each of the plurality of electrically conducting elements 302 may include connector 302c located at a top of the vertical portion 302a such that the top of the vertical portion 302a is electrically connected to an end of the horizontal portion 302b.

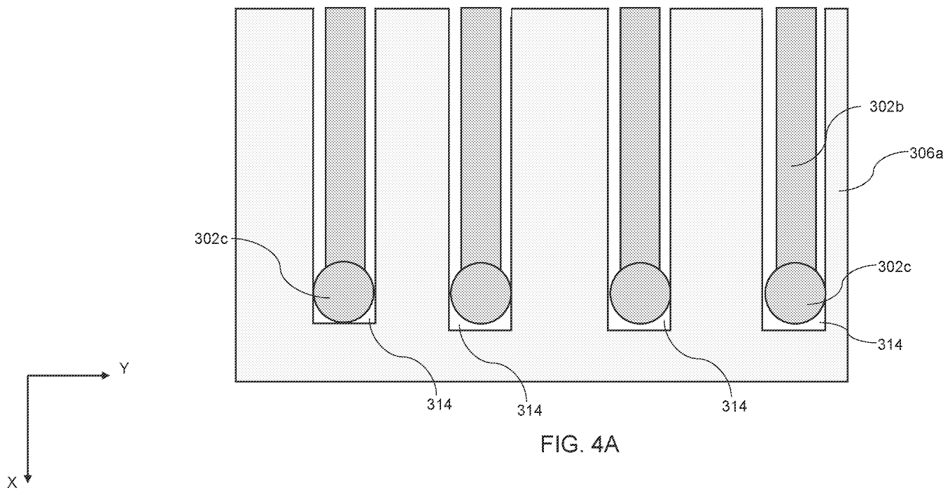

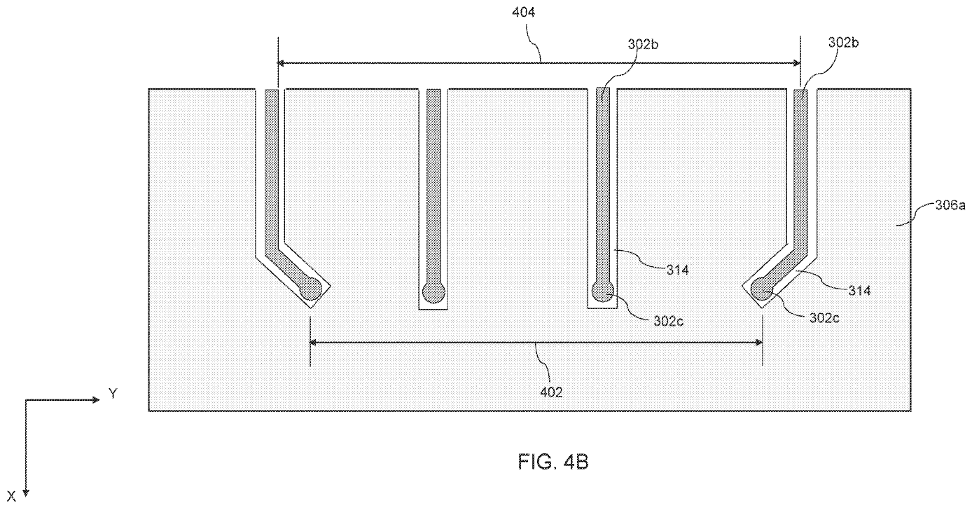

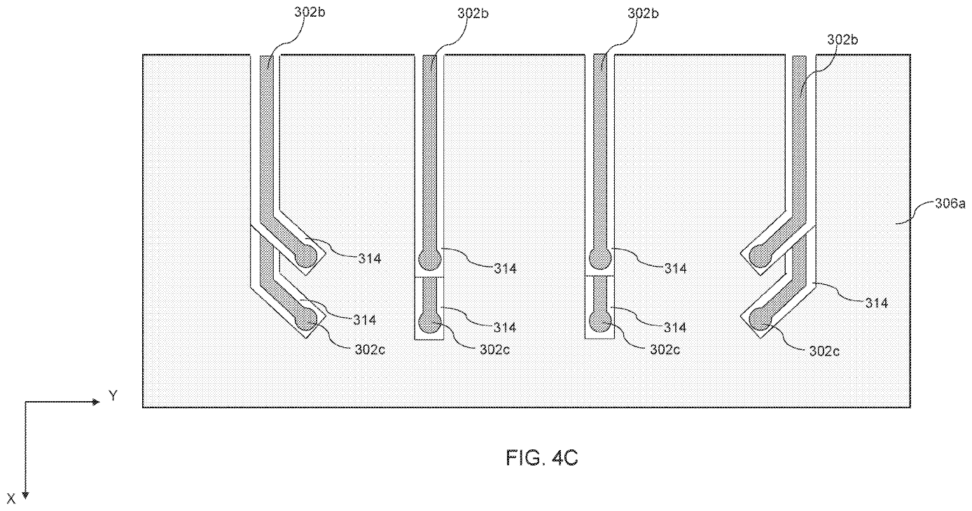

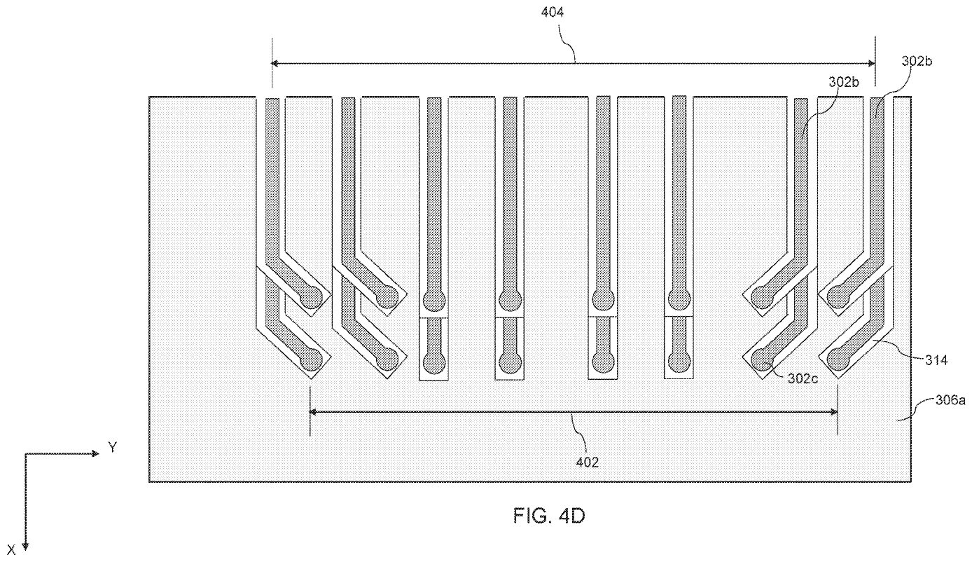

In one embodiment, the matrix 301 of the first connector 212a may include a plurality of plates 306 that extend horizontally parallel to the top surface of the photonic interposer 208 and are stacked vertically. For example, each of the plurality of plates 306 may be formed of a semiconductor (e.g., silicon), glass, ceramic, or polymer material. As shown in FIG. 3B, each plate 306 may include a first portion 306a and a second portion 306b. Each first portion 306a may support a respective horizontal portion 302b and each second portion 306b may support one or more vertical portions 302a. In this regard, each first portion 306a may include a groove 314 shown in FIG. 3D that supports the horizontal portion 302b of a respective one of the plurality of electrically conducting elements 302, as described in greater detail with reference to FIGS. 3D to 4E, below. Each horizontal portion 302b may be placed in a respective groove 314 and may be secured in the groove with an overlying adhesive material 308. The adhesive material 308 may be an epoxy material suitable for cryogenic applications. Each vertical portion 302a may be formed within a hole (e.g., a via opening) formed within one or more second portions 306b of the plurality of plates 306.

An interface between the first portions 306a and the second portions 306b of the plates may have a stair-step configuration, as shown in FIG. 3B. Further, the connector 302c of each of the plurality of electrically conducting elements may be located near the interface between the first portion 306a and the second portion 306b. As such, a height of the vertical portion 302a may be an increasing function of position along a first horizontal direction X (e.g., from left to right in FIG. 3B). Each vertical portion 302a may have a vertical symmetry axis 310, and symmetry axes 310 of respective vertical portions may be separated from one another horizontally such that the vertical portions 302a of the plurality of electrically conducting elements are configured as a two-dimensional array, as described in greater detail with reference to FIG. 3C, below.

A height of the vertical portion 302a may be a function of position within the two-dimensional array such that the height is an increasing function along the first horizontal direction X (i.e., from left to right in FIG. 3B) and may be a constant along a second horizontal direction Y that is orthogonal to the first horizontal direction X (e.g., into the plane of FIG. 3B; see FIGS. 3B, 3C, and 3D). As such, a vertical position of each of the plurality of plates 306 supporting the horizontal portion 302b of a respective one of the plurality of electrically conducting elements may correspond to a height of the vertical portion 302a connected to the horizontal portion 302b, as shown in FIG. 3B. In this way, each of the plurality of plates 306 supports a plurality of horizontal portions 302b separated from one another along the second horizontal direction Y (e.g., into the plane of FIG. 3B), as described in greater detail with reference to FIGS. 4A to 4E, below.

The vertical portions 302a of the plurality electrically conducting elements 302 may be electrically connected to the electrically conducting elements 307 of the electrical interposer 210a using electrically conductive bonding pads 312 and bonding structures 318, as will be described in more detail below with respect to FIGS. 3C and 6. Any suitable bonding structure material may be used for the bonding structures 318.

FIG. 3C is a horizontal cross-sectional view of a top surface of an electrical interposer (e.g., the first electrical interposer 210a) showing a plurality of electrically conductive bonding pads 312 located on the top surface of the electrical interposer, according to some embodiments. The plane defining the cross-sectional view of FIG. 3C is indicated by the cross-section C-C′ in FIG. 3B. The electrically conductive bonding pads 312 may be arranged in a periodic array (e.g., a square array, a hexagonal array, etc.), as shown. In further embodiments, the connectors may be arranged in various other geometric arrangements and need not have any specific order. The layout of the electrically conductive bonding pads 312 may correspond to an arrangement of the vertical portions 302a of the plurality of electrically conducting elements in the first connector 212a (e.g., see FIG. 3B). As such, each of the vertical portions 302a of the electrically conducting elements 302 may be electrically connected to a respective one of the electrically conductive bonding pads 312 via a respective bonding structure 318. In other embodiments, a number of the vertical portions 302a may correspond to a sub-set of the electrically conductive bonding pads 312, such that there are more electrically conductive bonding pads 312 than vertical portions 302a. Similarly, if not all of the vertical portions 302a are needed for a given circuit configuration, a number of electrically conductive bonding pads 312 may correspond to a sub-set of the vertical portions 302a such that there are more vertical portions 302a than bonding pads 312.

FIG. 3D is a vertical cross-sectional view of a portion of the first connector of FIG. 3B, according to some embodiments. The plane defining the cross-sectional view of FIG. 3D is indicated by the cross-section D-D′ in FIG. 3B. As shown in FIG. 3D, a plurality of vertical portions 302a of the plurality of electrically conducting elements 302 may be separated from one another along the second horizontal direction Y and may have a constant height. As described above with reference to FIG. 3B, the vertical portions 302a may be formed in holes/vias in the second portion 306b of a plate 306, while the connector 302c and horizontal portion 302b of each electrically conducting element may be supported by the first portion 306a of a plate 306. In this regard, the first portion 306a of a plate 306 may include a plurality of grooves 314 that may be configured to support the connectors 302c and the horizontal portions 302b (e.g., see FIG. 3B) of the electrically conductive elements 302. Further, as described above, an adhesive material 308 may be provided to secure the connectors 302c and the horizontal portions 302b within respective grooves 314 and to attach adjacent plates 306 to one another to form the stack of plates 306 shown in FIG. 3B. An optional flat cover plate 320, such as a flat glass plate without grooves, may be located over the upper most level of the horizontal portions 302b of electrically conducting elements 302 and their corresponding adhesive material 308. Further details of the first portion 306a of a plate 306 are described with reference to FIG. 4A, below.

FIG. 4A is a horizontal cross-sectional view of a first portion 306a of a plate 306 having grooves 314, according to some embodiments. The plane defining the cross-sectional view of FIG. 4A is indicated by the cross-section 4A-4A′ in FIGS. 3B and 3D. As shown, the first portion 306a of the plate 306 may include a plurality of grooves 314 extending along the first horizontal direction X and separated from one another along the second horizontal direction Y. As shown, each groove 314 may have a width that is sufficient to accommodate the connector 302c as well as the horizontal portion 302b. In this example, the first portion 306a of the plate 306 may include four grooves 314 to accommodate four horizontal portions 302b and four respective connectors 302c. Other embodiments may include greater or fewer numbers of grooves 314 to accommodate respective other numbers of horizontal portions 302b and connectors 302c. Other embodiments may also have different spatial arrangements of the grooves 314. For example, the arrangement of grooves 314 may include a fan-out configuration as described with reference to FIGS. 4B to 4D, below.

FIGS. 4B to 4D provide horizontal cross-sectional and top transparent views of plates having grooves arranged in various configurations, according to some embodiments. In the horizontal cross-sectional view of FIG. 4B, for example, the grooves 314 may be arranged in a fan-out configuration as shown. In this regard, the grooves 314 may have an arrangement in which a pitch between the grooves 314 along the second horizontal direction Y increases as a function of distance along the first horizontal direction X. As shown, in this example embodiment, the two outermost grooves 314 may have a first spacing 402 between them along the second direction Y at a first position along the first horizontal direction X and a second spacing 404 between them along the second direction Y at a second position along the first horizontal direction X. This example embodiment illustrates a fan-out configuration in which some of the grooves 314 have a straight shape (e.g., the two central grooves) and others have a non-straight (e.g., bent) shape (e.g., the two outside grooves). As such, some of the spacings between adjacent grooves 314 (i.e., groove pitch along the second direction Y) may be constant as a function of distance along the first direction X (e.g., as with the two center grooves 314) and some spacings between adjacent grooves 314 may vary as a function of position along the first direction X. Various other configurations of grooves 314 may be provided in other embodiments.

FIGS. 4C and 4D are transparent top views of two stacked plates showing relative placements of grooves, according to some embodiments. The embodiment of FIG. 4C may be obtained by stacking two plates having a fan-out configuration such as the fan-out configuration described above with reference to FIG. 4B. As shown, the plates may be displaced relative to one another along the first horizontal direction X, as described in greater detail with reference to FIG. 3B, above. FIG. 4D illustrates a similar top transparent view of two stacked plates showing relative placement of grooves, according to some embodiments. In this example embodiment, each of the two stacked plates may include eight grooves having a fan-out configuration. For example, the left two grooves 314 and the right two grooves 314 may each have a bent configuration while the central four grooves 314 may have a straight configuration. As such, a first spacing 402 between the two outermost grooves 314 along the second horizontal direction Y, at a first position along the first direction X, may be smaller than a second spacing 404 between them along the second horizon direction Y, at a second position along the first horizontal direction X. As with the embodiment of FIG. 4C, the two stacked plates may be displaced relative to one another along the first horizontal direction X, as described in greater with reference to FIG. 3B, above.

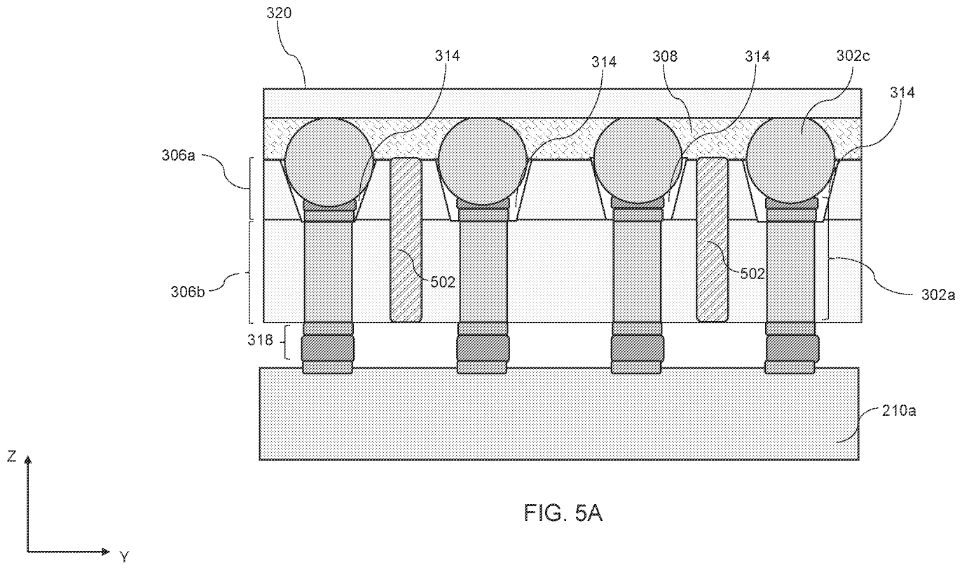

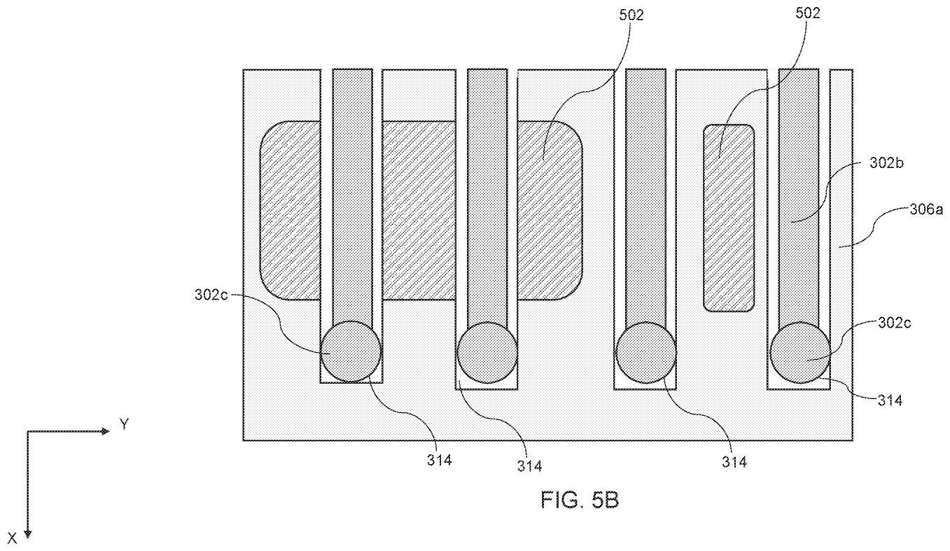

FIG. 5A is a vertical cross-sectional view of a portion of the first connector of FIG. 3A in which the plate includes passive electrical components 502, and FIG. 5B is a horizontal cross-sectional view of a first portion 306a of a plate 306 having passive electrical components 502, according to alternative embodiments. The passive electrical components 502 may include at least one of a resistor, capacitor and/or inductor and may be included to modify electrical characteristics of the electrically conductive elements 302. For example, passive electrical components 502 may be used to tune electrical resonances to maximize power transfer while minimizing resistive loss. The passive electrical components 502 may be formed in various ways. For example, resistors, inductors, and capacitors may be formed as separate stand-alone components that may be attached to the plates 306. Alternatively, passive electrical components 502 may be embedded within the plates 306 or may be formed in a cavity/recess formed in a surface of one or more plates 306.

FIG. 6 is a vertical cross-sectional view of a vertical portion 302a and a connector 302c of one of a plurality of electrically conducting elements 302, according to some elements. As shown, the vertical portion 302a may include a multi-layer stack of materials. In this example embodiment, the multi-layer stack may include copper indium, gold, and electroless nickel immersion gold. As shown, the vertical portion 302a may be electrically coupled via a bonding structure 318 to a bonding pad 312 of a redistribution layer (RDL) of the first electrical interposer 210a. The bonding pad 312 may be formed of an electrically conductive material, such as copper. An optional conductive cap 312a, such as electroless nickel immersion gold (i.e., electrolessly plated nickel immersed in gold) cap may be formed over the copper bonding pad 312.

The bonding structure 318 may comprise any suitable bonding material 318a, such as indium or solder. An optional conductive bonding cap, such as a gold cap 318b, may be formed over the bonding material 318a.

The vertical portion 302a of the electrically conducting element 302 may comprise a copper wire or trace 604a that is deposited in a via opening in the conductive plate 306. The copper wire or trace 604a may contact the underlying gold cap 318b. An optional conductive via cap, such as a gold cap 604b, may be formed over the copper wire or trace 604a.

Another bonding material 604c, such as indium or solder may be located between the vertical portion 302a and the connector 302c. The bonding material 604c may be located over the gold cap 604, and the connector 302c may comprise a copper wire or trace that is bonded to the vertical portion 302a using the bonding material 604c. Alternatively, a gold to gold bond may be used to bond the conductive wires or traces to each other. In this case, the connector 302c may comprise a gold ball.

The various materials and thicknesses of the layers in the multi-layer stack may be chosen to have advantageous electrical and thermal expansion properties. In this regard, a temperature gradient may exist between the first electrical interposer 210a and the connector 302c during operation. Therefore, the multi-layer stack may be optimized to accommodate differential expansion of the vertical portion 302a during operation.

FIGS. 7A to 7D illustrate further details of a cable 214 that may be used to connect a first die stack 202a to a second die stack 202b (e.g., see FIGS. 2A to 2C), according to some embodiments. FIG. 7A shows a side view of the cable 214 having the plurality of additional electrically conductive elements 304. FIG. 7B is a vertical cross-sectional view of the cable 214 illustrating a plurality of the additional electrically conductive elements 304. The plane defining the cross-sectional view of FIG. 7B is indicated by the cross-section B-B′ in FIG. 7A. As described above, the additional electrically conductive elements 304 may be formed with and supported by the matrix material 303. The matrix material 303 may be a flexible polymer (e.g., polyimide) material. FIG. 7C illustrates an enlarged view of a region 7C shown in FIG. 7B showing a first example of one of the additional electrically conductive elements 304. In this example, the electrically conductive element 304 may be a single wire made of an electrically conductive material, such as copper. In a further embodiment, the electrically conductive element 304 may be a composite wire including a core 704 having a first electrically conductive material and a cladding 706 formed of a second electrically conductive material as shown in FIG. 7D. For example, the core 704 may be a metal such as aluminum or copper and the cladding 706 may be a low temperature superconducting material, such as niobium.

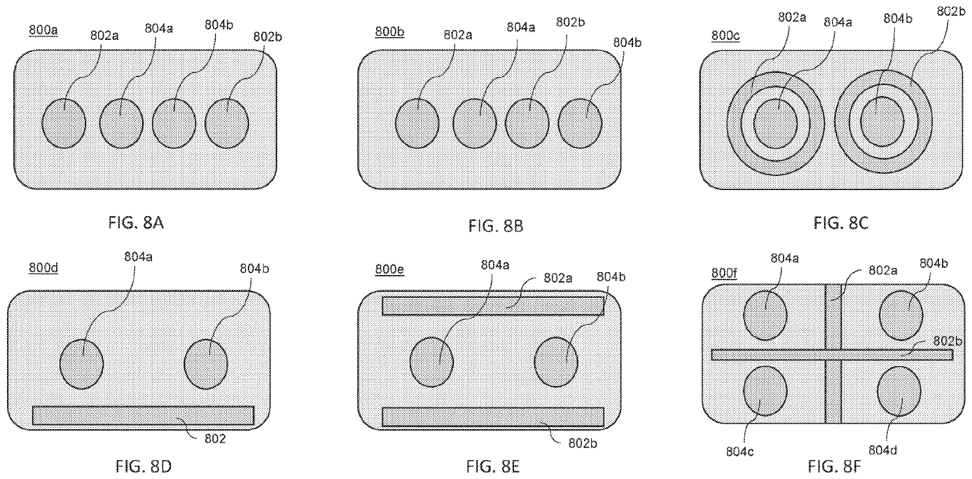

FIGS. 8A to 8F illustrate vertical cross-sectional views of various electrical conductors (800a, 800b, 800c, 800d, 800e, 800f) that may be used in place of the embodiments described above with reference to FIGS. 7B to 7D, according to some embodiments. In various embodiments, the electrical conductors (800a, 800b, 800c, 800d, 800e, 800f) may exhibit improved electrical signaling characteristics relative to the single-wire electrically conductive elements 304 of FIGS. 7B to 7D. FIG. 8A illustrates a differential pair conductor 800a that may be used in a differential signaling protocol (e.g., using low-voltage differential signaling). In this regard, the differential pair conductor 800a may include a grounded pair of conductors 802 and a signaling pair of conductors 804. The grounded pair of conductors 802 may include a first grounded conductor 802a and a second grounded conductor 802b, which each may be held at a ground potential. The signaling pair of conductors 804 may further include a first signaling conductor 804a and a second signaling conductor 804b. A first signal may propagate on the first signaling conductor 804a and a second signal may propagate on the second signaling conductor 804b. Each of the first signal and the second signal may have a voltage that is equal in magnitude but opposite in polarity. A receiving circuit may respond to a difference between the two signals thereby generating a signal having twice the voltage.

FIG. 8B is a vertical cross-sectional view of an example electrical conductor 800b configured as a coplanar waveguide, according to some embodiments. As shown, the electrical conductor 800b may be similar to the electrical conductor 800a of FIG. 8A, with the exception of how voltages are applied to the grounded pair of conductors 802 and the signaling pair of conductors 804. In this regard, the grounded pair of conductors 802 may be interspersed with the signaling pair of conductors 804 such that the first grounded conductor 802a and the second grounded conductor 802b are separated by the first signaling conductor 804a. Similarly, the signaling pair of conductors 804 may be interspersed with the grounded pair of conductors 802 such that the first signaling conductor 804a and the second signaling conductor 804b are separated by the second grounded conductor 802b.

FIG. 8C is a vertical cross-sectional view of an example electrical conductor 800c configured as a pair of coaxial conductors, according to some embodiments. In this regard, each of the pair of coaxial conductors may include a core conductor and a shell conductor. The shell conductors may respectively be configured as the first grounded conductor 802a and the second grounded conductor 802b, as shown. Similarly, the core conductors may be configured as the first signaling conductor 804a and the second signaling conductor 804b. The presence of the first grounded conductor 802a and the second grounded conductor 802b may act to reduce electrical interference between the signaling conductors (804a, 804b).

FIGS. 8D and 8E illustrate electrical conductors configured as a strip line conductor 800d and a micro-strip line conductor 800e, respectively. As shown, the strip line conductor 800d of FIG. 8D may include a single grounded strip conductor 802 along with a first signaling conductor 804a and a second signaling conductor 804b. The micro-strip line conductor 800e of FIG. 8E may have two strip line conductors respectively configured as the first grounded conductor 802a and the second grounded conductor 802b. As shown in FIG. 8E, a first signaling conductor 804a and a second signaling conductor 804b may be formed in a space between the first grounded conductor 802a and the second grounded conductor 802b.

FIG. 8F is a vertical cross-sectional view of a shielded conductor 800f, according to some embodiments. As shown in FIG. 8F, the shielded conductor 800f may include a plurality of signaling conductors separated by grounded strip conductors. In this regard, the shielded conductor 800f may include a first grounded conductor 802a and a perpendicular second grounded conductor 802b. The first grounded conductor 802a and the second grounded conductor 802b may be interspersed between four signaling conductors. As shown, the four signaling conductors may include a first signaling conductor 804a, a second signaling conductor 804b, a third signaling conductor 804c, and a fourth signaling conductor 804d. The presence of the first grounded conductor 802a and the second grounded conductor 802b may act to reduce electrical interference between the signaling conductors (804a, 804b, 804c, 804d).

FIGS. 9A to 9F illustrate vertical cross-sectional views of various electrical conductors (900a, 900b, 900c, 900d, 900e, 900f) that may be used in place of the embodiments described above with reference to FIGS. 7B to 8F, according to some embodiments. In this regard, each of the electrical conductors (900a, 900b, 900c, 900d, 900e, 900f) has a structure similar to that of the respective electrical conductors (800a, 800b, 800c, 800d, 800e, 800f) with the exception that each first grounded conductor 802a, each second grounded conductor 802b, each first signaling conductor 804a, each second signaling conductor 804b, and the single grounded conductor 802 in conductor 900d further include a superconducting material. For example, each of the above-described conductors may include a core 704 having a first electrically conductive material and a cladding 706 formed of a second electrically conductive material. For example, the core 704 may be a metal such as aluminum or copper and the cladding 706 may be a superconducting material, such as niobium.

FIGS. 10A to 10F illustrate vertical cross-sectional views of various electrical conductors (1000a, 1000b, 1000c, 1000d, 1000e, 1000f) that may be used in place of the embodiments described above with reference to FIGS. 7B to 9F, according to some embodiments. In this regard, each of the electrical conductors (1000a, 1000b, 1000c, 1000d, 1000e, 1000f) has a structure similar to that of the respective electrical conductors (900a, 900b, 900c, 900d, 900e, 900f) with the exception that each of the electrical conductors (1000a, 1000b, 1000c, 1000d, 1000e, 1000f) may be surrounded by an optical shield 1002. In this regard, each of the each of the electrical conductors (1000a, 1000b, 1000c, 1000d, 1000e, 1000f) may be formed within a region of a matrix material 303. A shielding material may then be applied to cover outer surfaces of the matrix material 303. According to an embodiment, the shielding material may be black or carbon-based paint. The electrical conductors (1000a, 1000b, 1000c, 1000d, 1000e, 1000f) may then be bundled together to form the cable 214 shown in FIG. 7A, for example.

Embodiment electrical couplers disclosed herein, may provide advantages for use at cryogenic temperatures. In this regard, the disclosed electrical couplers may include materials having thermal expansion coefficients that are matched to other components to which they are mechanically coupled. As such, disclosed embodiment electrical couplers may avoid degradation and damage due to thermal expansion mismatch that may otherwise occur using couplers designed for higher temperature use.

In addition to quantum computing and cryogenic electronics applications, the assemblies of various disclosed embodiments may be used in datacom/telecom systems, integrated optics systems, as well as artificial intelligence systems which rely on co-integration of photonics with advanced CMOS. In this regard, heat removal and thermal control over localized regions of the photonic die elements may provide additional design flexibility for co-integration of complex ASIC circuits that generate heat with the photonic integrated circuits that typically include temperature sensitive integrated components, such as detectors (e.g., superconducting detectors), lasers, modulators, single-photon sources, etc.

The following are example embodiments:

Example 1: A hybrid electronic/photonic device, comprising: a first photonic die comprising first photonic components; a first electronic die electrically connected to the first photonic die; a first electrical interposer bonded to the first electronic die; and an electrical coupler coupled to the first electrical interposer such that at least a first portion of the electrical coupler coupled to the first electrical interposer and the first electrical interposer have respective coefficients of thermal expansion that differ by 10% or less.

Example 2: The hybrid electronic/photonic device as example 1 describes, wherein the first portion of the electrical coupler comprises a first connector comprising a semiconductor or insulating matrix embedding electrically conducting elements.

Example 3: The hybrid electronic/photonic device as either of examples 1 or 2 describe, wherein: the first electrical interposer comprises an interposer matrix embedding electrically conducting interposer elements; and the interposer matrix comprises a same material as the semiconductor or insulating matrix of the first connector.

Example 4: The hybrid electronic/photonic device as any of examples 1-3 describe, wherein: the semiconductor or insulating matrix comprises a silicon, a glass, a ceramic, or a polymer material; and each of the electrically conducting elements comprises a vertical portion and a horizontal portion.

Example 5: The hybrid electronic/photonic device as any of examples 1-4 describe, wherein each of the plurality of electrically conducting elements further comprises an electrically conductive connector located at a top of the vertical portion such that the top of the vertical portion is electrically connected to an end of the horizontal portion.

Example 6: The hybrid electronic/photonic device as any of examples 1-5 describe, wherein: the semiconductor or insulating matrix of the first connector comprises a plurality of plates that extend horizontally and are stacked vertically; and each of the plurality of plates comprises a groove that supports the horizontal portion of a respective one of the plurality of electrically conducting elements.

Example 7: The hybrid electronic/photonic device as any of examples 1-6 describe, wherein: the vertical portion comprises a vertical symmetry axis and symmetry axes of respective vertical portions are separated from one another horizontally such that the vertical portions of the plurality of electrically conducting elements are configured as a two-dimensional array; a height of the vertical portion is a function of position within the two-dimensional array such that the height is an increasing function along a first horizontal direction and is a constant along a second horizontal direction that is orthogonal to the first horizontal direction; and a vertical position of each of the plurality of plates supporting the horizontal portion of a respective one of the plurality of electrically conducting elements corresponds to the height of the vertical portion connected to the horizontal portion such that each of the plurality of plates supports a plurality of horizontal portions separated from one another along the second horizontal direction.

Example 8: The hybrid electronic/photonic device as any of examples 1-7 describe, wherein: a plurality of grooves in each of the plurality of plates comprises a fan out configuration having a spacing between adjacent grooves along the second horizontal direction that increases as a function of distance along the first horizontal direction; and the electrically conducting elements comprise a differential pair conductor, a coplanar waveguide, a coaxial conductor, a strip line, a microstrip line, or a shielded waveguide.

Example 9: The hybrid electronic/photonic device as any of examples 1-8 describe, wherein the first connector further comprises at least one of a resistor, a capacitor, or an inductor.

Example 10: The hybrid electronic/photonic device as any of examples 1-9 describe, wherein the electrical coupler further comprises a rigid first support portion which supports the first connector above a top surface of the first electrical interposer.

Example 11: The hybrid electronic/photonic device as any of examples 1-10 describe, further comprising: a second photonic die comprising second photonic components; a second electronic die electrically connected to the second photonic die; and a second electrical interposer bonded to the second electronic die, wherein the electrical coupler is further coupled to the second electrical interposer such that at least a second portion of the electrical coupler coupled to the second electrical interposer and the second electrical interposer have respective coefficients of thermal expansion that differ by 10% or less.

Example 12: The hybrid electronic/photonic device as any of examples 1-11 describe, further comprising a photonic interposer optically coupled to and supporting the first photonic die and the second photonic die.

Example 13: The hybrid electronic/photonic device as any of examples 1-12 describe, wherein the electrical coupler further comprises: a second connector comprising the second portion of the electrical coupler which is coupled to the second electrical interposer; a flexible cable electrically coupling the first connector to the second connector; and rigid support structure supporting the first connector and the second connector above a top surface of the photonic interposer.

Example 14: The hybrid electronic/photonic device as any of examples 1-13 describe, wherein: the first electrical interposer is located vertically between the first electronic die and the first photonic die; the first electronic die is laterally offset from an edge of a top surface of the first electrical interposer; and the first connector is electrically coupled to a portion of the top surface of the first electrical interposer that is exposed on a side of the laterally offset first electronic die.

Example 15: The hybrid electronic/photonic device as any of examples 1-14 describe, wherein: the first electronic die is bonded to a top of the first photonic die; and a first electrical interposer is bonded a top of the first electronic die.

Example 16: A hybrid electronic/photonic device, comprising: a substrate; first and second die stacks located over the substrate; and an electrical coupler electrically coupling the first and the second die stacks; wherein: the first die stack comprises a first photonic die comprising first photonic components, a first electronic die electrically connected to the first photonic die, and a first electrical interposer bonded to the first electronic die; the second die stack comprises a second photonic die comprising second photonic components, a second electronic die electrically connected to the second photonic die, and second electrical interposer bonded to the second electronic die; and the electrical coupler comprises a rigid first connector comprising a semiconductor or insulating matrix embedding electrically conducting elements which are electrically connected to the first electrical interposer, a rigid second connector comprising a semiconductor or insulating matrix embedding electrically conducting elements which are electrically connected to the second electrical interposer, and a flexible cable located above the substrate and electrically connecting the rigid first and second connectors.

Example 17: The hybrid electronic/photonic device as examples 16 describes, wherein: the substrate comprises a photonic interposer optically coupled to and supporting the first photonic die and the second photonic die; and the electrical coupler further comprises a rigid support structure supporting the rigid first connector and the rigid second connector above a top surface of the photonic interposer.

Example 18: The hybrid electronic/photonic device as either of examples 16 or 17 describe, wherein: the first electrical interposer is located vertically between the first electronic die and the first photonic die; the first electronic die is laterally offset from an edge of a top surface of the first electrical interposer; and the first connector is electrically coupled to a portion of the top surface of the first electrical interposer that is exposed on a side of the laterally offset first electronic die.

Example 19: The hybrid electronic/photonic device as any of examples 16-18 describe, wherein: the first electronic die is bonded to a top of the first photonic die; and a first electrical interposer is bonded a top of the first electronic die.

Example 20: The hybrid electronic/photonic device as any of examples 16-19 describe, wherein: the rigid first connector and the first electrical interposer have respective coefficients of thermal expansion that differ by 10% or less; and the rigid second connector and the second electrical interposer have respective coefficients of thermal expansion that differ by 10% or less.

The terminology used in the description of the various described embodiments herein is for the purpose of describing particular embodiments only and is not intended to be limiting. As used in the description of the various described embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A hybrid electronic/photonic device, comprising:
a first photonic die comprising first photonic components;
a first electronic die electrically connected to the first photonic die;
a first electrical interposer bonded to the first electronic die; and
an electrical coupler coupled to the first electrical interposer such that at least a first portion of the electrical coupler coupled to the first electrical interposer and the first electrical interposer have respective coefficients of thermal expansion that differ by 10% or less.

2. The hybrid electronic/photonic device of claim 1, wherein the first portion of the electrical coupler comprises a first connector comprising a semiconductor or insulating matrix embedding electrically conducting elements.

3. The hybrid electronic/photonic device of claim 2, wherein:
the first electrical interposer comprises an interposer matrix embedding electrically conducting interposer elements; and
the interposer matrix comprises a same material as the semiconductor or insulating matrix of the first connector.

4. The hybrid electronic/photonic device of claim 2, wherein:
the semiconductor or insulating matrix comprises a silicon, a glass, a ceramic, or a polymer material; and
each of the electrically conducting elements comprises a vertical portion and a horizontal portion.

5. The hybrid electronic/photonic device of claim 4, wherein each of the plurality of electrically conducting elements further comprises an electrically conductive connector located at a top of the vertical portion such that the top of the vertical portion is electrically connected to an end of the horizontal portion.

6. The hybrid electronic/photonic device of claim 4, wherein:
the semiconductor or insulating matrix of the first connector comprises a plurality of plates that extend horizontally and are stacked vertically; and
each of the plurality of plates comprises a groove that supports the horizontal portion of a respective one of the plurality of electrically conducting elements.

7. The hybrid electronic/photonic device of claim 6, wherein:
the vertical portion comprises a vertical symmetry axis and symmetry axes of respective vertical portions are separated from one another horizontally such that the vertical portions of the plurality of electrically conducting elements are configured as a two-dimensional array;
a height of the vertical portion is a function of position within the two-dimensional array such that the height is an increasing function along a first horizontal direction and is a constant along a second horizontal direction that is orthogonal to the first horizontal direction; and
a vertical position of each of the plurality of plates supporting the horizontal portion of a respective one of the plurality of electrically conducting elements corresponds to the height of the vertical portion connected to the horizontal portion such that each of the plurality of plates supports a plurality of horizontal portions separated from one another along the second horizontal direction.

8. The hybrid electronic/photonic device of claim 7, wherein:
a plurality of grooves in each of the plurality of plates comprises a fan out configuration having a spacing between adjacent grooves along the second horizontal direction that increases as a function of distance along the first horizontal direction; and
the electrically conducting elements comprise a differential pair conductor, a coplanar waveguide, a coaxial conductor, a strip line, a microstrip line, or a shielded waveguide.

9. The hybrid electronic/photonic device of claim 2, wherein the first connector further comprises at least one of a resistor, a capacitor, or an inductor.

10. The hybrid electronic/photonic device of claim 2, wherein the electrical coupler further comprises a rigid first support portion which supports the first connector above a top surface of the first electrical interposer.

11. The hybrid electronic/photonic device of claim 2, further comprising:
a second photonic die comprising second photonic components;
a second electronic die electrically connected to the second photonic die; and
a second electrical interposer bonded to the second electronic die,
wherein the electrical coupler is further coupled to the second electrical interposer such that at least a second portion of the electrical coupler coupled to the second electrical interposer and the second electrical interposer have respective coefficients of thermal expansion that differ by 10% or less.

12. The hybrid electronic/photonic device of claim 11, further comprising a photonic interposer optically coupled to and supporting the first photonic die and the second photonic die.

13. The hybrid electronic/photonic device of claim 12, wherein the electrical coupler further comprises:
a second connector comprising the second portion of the electrical coupler which is coupled to the second electrical interposer;
a flexible cable electrically coupling the first connector to the second connector; and
rigid support structure supporting the first connector and the second connector above a top surface of the photonic interposer.

14. The hybrid electronic/photonic device of claim 2, wherein:
the first electrical interposer is located vertically between the first electronic die and the first photonic die;
the first electronic die is laterally offset from an edge of a top surface of the first electrical interposer; and
the first connector is electrically coupled to a portion of the top surface of the first electrical interposer that is exposed on a side of the laterally offset first electronic die.

15. The hybrid electronic/photonic device of claim 1, wherein:
the first electronic die is bonded to a top of the first photonic die; and
a first electrical interposer is bonded a top of the first electronic die.

16. A hybrid electronic/photonic device, comprising:
a substrate;
first and second die stacks located over the substrate; and
an electrical coupler electrically coupling the first and the second die stacks;
wherein:
the first die stack comprises a first photonic die comprising first photonic components, a first electronic die electrically connected to the first photonic die, and a first electrical interposer bonded to the first electronic die;
the second die stack comprises a second photonic die comprising second photonic components, a second electronic die electrically connected to the second photonic die, and second electrical interposer bonded to the second electronic die; and
the electrical coupler comprises a rigid first connector comprising a semiconductor or insulating matrix embedding electrically conducting elements which are electrically connected to the first electrical interposer, a rigid second connector comprising a semiconductor or insulating matrix embedding electrically conducting elements which are electrically connected to the second electrical interposer, and a flexible cable located above the substrate and electrically connecting the rigid first and second connectors.

17. The hybrid electronic/photonic device of claim 16, wherein:
the substrate comprises a photonic interposer optically coupled to and supporting the first photonic die and the second photonic die; and
the electrical coupler further comprises a rigid support structure supporting the rigid first connector and the rigid second connector above a top surface of the photonic interposer.

18. The hybrid electronic/photonic device of claim 16, wherein:
the first electrical interposer is located vertically between the first electronic die and the first photonic die;
the first electronic die is laterally offset from an edge of a top surface of the first electrical interposer; and
the first connector is electrically coupled to a portion of the top surface of the first electrical interposer that is exposed on a side of the laterally offset first electronic die.

19. The hybrid electronic/photonic device of claim 16, wherein:
the first electronic die is bonded to a top of the first photonic die; and
a first electrical interposer is bonded a top of the first electronic die.

20. The hybrid electronic/photonic device of claim 16, wherein:
the rigid first connector and the first electrical interposer have respective coefficients of thermal expansion that differ by 10% or less; and
the rigid second connector and the second electrical interposer have respective coefficients of thermal expansion that differ by 10% or less.
